(19) United States
(12) Patent Application Publication
(10) Pub. No.: US 2026/0360446 A1
(43) Pub. Date: Nov. 12, 2026

(54) MULTIPLE VOLTAGE DIFFERENTIATION

(71) Applicant: Micron Technology, Inc., Bosie, ID (US)

(72) Inventors: Michele Piccardi, Cupertino, CA (US); Kitae Park, San Jose, CA (US); Junghee Yun, Fremont, CA (US)

(73) Assignee: Micron Technology, Inc., Boise, ID (US)

(21) Appl. No.: 19/653,822

(22) Filed: Apr. 21, 2026

Related U.S. Application Data
(60) Provisional application No. 63/802,476, filed on May 8, 2025.

(51) Int. Cl. G11C 16/30; G11C 5/14; G11C 16/10; G11C 16/32

(52) U.S. Cl. CPC G11C 16/30; G11C 5/145; G11C 16/102; G11C 16/32

(57) ABSTRACT

Methods, systems, and devices for techniques for multiple voltage differentiation for a NAND memory device. The NAND memory device may include an array of memory cells comprising a plurality of memory cells. The NAND memory device may further include a first supply voltage pad configured to receive a first supply voltage (Vcc1), a second supply voltage pad configured to receive a second supply voltage (Vcc2), the second supply voltage being higher than the first supply voltage, and a charge pump. The charge pump may include a booster configured to generate a boost voltage based on the second supply voltage and a clock driver configured to provide timing signals for the booster using the first supply voltage.

### CROSS REFERENCE TO RELATED APPLICATIONS

This application claims priority to U.S. Application No. 63/802,476, filed on May 8, 2025, and is entitled “MULTIPLE VOLTAGE DIFFERENTIATION,” the content of which is incorporated by reference in its entirety herein for all purposes.

### TECHNICAL FIELD

This disclosure relates to one or more systems for memory, including techniques for power supply differentiation, and in particular, for systems of providing multiple levels of voltages to a memory device and a method of controlling the multiple levels of voltages.

### BACKGROUND

Memory devices are widely used to store information in devices such as computers, user devices, wireless communication devices, cameras, digital displays, and others. Information is stored by programming memory cells within a memory device to various states. For example, binary memory cells may be programmed to one of two supported states, often denoted by a logic 1 or a logic 0. In some examples, a single memory cell may support more than two states, any one of which may be stored. To access the stored information, the memory device may read (e.g., sense, detect, retrieve, determine) states from the memory cells. To store information, the memory device may write (e.g., program, set, assign) states to the memory cells. Information can also be erased from the memory cells and new information can be stored in the memory cells.

Various types of memory devices exist, including magnetic hard disks, random access memory (RAM), read-only memory (ROM), dynamic RAM (DRAM), synchronous dynamic RAM (SDRAM), static RAM (SRAM), ferroelectric RAM (FeRAM), magnetic RAM (MRAM), resistive RAM (RRAM), flash memory, phase change memory (PCM), self-selecting memory, chalcogenide memory technologies, not-or (NOR) and not-and (NAND) memory devices, and others. Memory cells may be described in terms of volatile configurations or non-volatile configurations. Memory cells configured in a non-volatile configuration may maintain stored logic states for extended periods of time even in the absence of an external power source. Memory cells configured in a volatile configuration may lose stored states when disconnected from an external power source.

### BRIEF DESCRIPTION OF THE DRAWINGS

FIG. 1 is a block diagram of a memory device in communication with a memory system controller of a memory system that support techniques for improving efficiency of power provided to the memory device, in accordance with examples as disclosed herein.

FIGS. 2A-2C are illustrative schematics of portions of an array of memory calls in a memory device, in accordance with examples as disclosed herein.

FIG. 2D illustrates an example of a memory device including multiple blocks of memory cells in accordance with examples as disclosed herein.

FIG. 3 is a block diagram of an example apparatus for implementing one or more systems and for performing one or more methods described herein, in accordance with examples as disclosed herein.

FIG. 4 illustrates example elements of a memory device related to implementing power supply differentiation , in accordance with examples as disclosed herein.

FIG. 5 illustrates example elements of a NAND memory device related to implementing programming voltage differentiation, in accordance with examples as disclosed herein

FIG. 6 illustrates an example charge pump, in accordance with examples as disclosed herein.

FIG. 7 illustrates a flowchart showing a method or methods that support techniques for pass voltage determination in accordance with examples as disclosed herein.

### DETAILED DESCRIPTION

A memory device frequently receives commands for read, write, and/or erase operations. A memory controller communicates with memory cells (e.g., NAND cells) to send instructions for such commands. The operations rely on different voltage levels used to manipulate the charge stored in the memory cells. For instance, the memory cells of NAND flash include charge trap cells configured to store charge. The charge trap cells use non-conductive materials to trap electrons in localized states. The electrons become localized in the traps, altering the electric field seen by the control gate. The charge increases the threshold voltage of the memory cell, which determines whether the memory cell may conduct current or not when read.

For example, the read operation detects the current flowing through the cell when a voltage is applied. The presence or absence of current reveals the stored bit(s). The read voltage is applied to the control gate, and the channel turns on or off based on the threshold voltage which is determined based on the trapped charge. A sense amplifier measures whether current flows through the cell to read. During a write operation (or also referred to as a program operation), electrons are injected into the trap layer of the memory cell to shift the threshold voltage. A high program voltage is applied to the control gate, such that electrons tunnel to the charge trap layer. The trapped electrons increase the threshold voltage such that the cell may be programmed. During an erase operation, a negative voltage is applied to the control gate and positive voltage is applied to the substrate. Electrons tunnel out of the trap layer back to the substrate which reduces the threshold voltage, resetting the cell to the erased state.

Different voltages provided to the NAND are controlled such that the voltages may be used for different parts and/or operations in a suitable manner. For example, supply voltage (Vcc) is configured to power the core logic circuits of the NAND flash memory, such as the control circuitry and charge pumps. The high voltage used in different operations (e.g., write, erase, etc.) may be referred to as the programming power voltage (Vpp). The NAND flash memory receives such voltages from external power sources via external power circuitry.

Existing external power circuitry for Vcc includes a step-down voltage regulator or a buck converter. For example, the buck converter is used to convert a higher input voltage to a desired Vcc for NAND flash memory. For example, in general, a voltage from the external voltage source is provided at 12 V. The 12V is converted to a lower operating Vcc for the NAND, which is commonly around 2.5 V. The external power circuitry also stabilizes the Vpp using a step-down voltage regulator and a step-up regulator (buck-boost converter). For example, the 12 V from the external power source may be converted to a lower voltage and then back up to 12 V. Such process may help provide a stable and regulated Vpp for the NAND. The buck-boost converter may help regulate the Vpp to a desired level.

However, such existing external power circuitry fails to provide the Vcc and the Vpp to the NAND in an efficient manner. For example, required energy per bit (EPB) may be high, decreasing the efficiency. The EPB may refer to amount of energy required to perform a particular operation on a single bit of data in the memory. Increased EPB negatively affects the efficiency by requiring higher more energy to perform an operation per bit. In particular, the efficiency of the Vcc decreases as the Vcc gets further from the original voltage (e.g., 12 V). However, to accommodate common operating voltages for different components of the NAND, the Vcc is relatively far from 12 V (e.g., around 2.5 V) which decreases the efficiency. Additionally, the efficiency of Vpp with respect to the existing power circuity may also be lower due to the use of a buck converter and a boost converter. For example, the combination of a buck converter and a boost converter generates the Vpp within a range with lower regulator or converter efficiency.

Techniques and circuits described herein provide an external power circuitry configured to provide multiple Vcc voltages and/or multiple Vpp voltages to a NAND and how the NAND implements such multiple Vcc voltages and the multiple Vpp voltages. The external power circuitry is configured to provide a first Vcc (Vcc1) and a second Vcc (Vcc2) to the NAND. The second Vcc is configured to be higher than the first Vcc. The first Vcc may be used to power different logical components of the NAND. The second Vcc may be used to provide higher voltage to different components without needing to increase or further boost the first Vcc. For example, the second Vcc may be used to provide a higher voltage to charge pumps. The charge pumps may utilize the higher second Vcc for booster to pump the voltages input to the charge pumps. As the higher voltage may be used without additional booster stages, the second Vcc may reduce the efficiency losses associated with the booster stages. In some embodiments, the second Vcc may be referred to Vcc-High (Vcch). The multiple Vpp voltages may include a higher Vpp and a lower Vpp. The controller of the NAND may select between the higher Vpp and the lower Vpp based on the type of operation being performed by the NAND. For example, the higher Vpp may be used for the program operation and the lower Vpp may be used for the read operation. The multiple Vpp voltages may be provided in an efficient manner (e.g., with reduced regulator losses). Additionally, the separate Vpp voltages provide voltages suitable for different operations without additional voltage regulators.

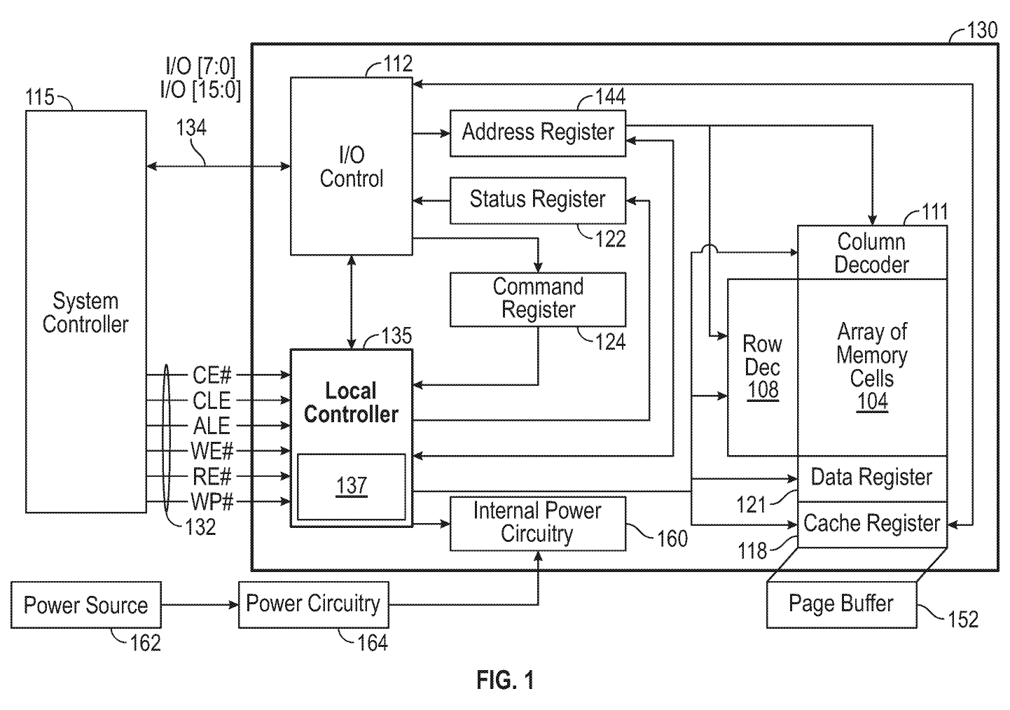

FIG. 1 is a simplified block diagram of a memory device 130 in communication with a system controller 115 of a memory system, according to an embodiment. A memory system may be or include any device or collection of devices, where the device or collection of devices includes at least one memory array. For example, a memory system may be or include a Universal Flash Storage (UFS) device, an embedded Multi-Media Controller (eMMC) device, a flash device, a universal serial bus (USB) flash device, a secure digital (SD) card, a solid-state drive (SSD), a hard disk drive (HDD), a dual in-line memory module (DIMM), a small outline DIMM (SO-DIMM), or a non-volatile DIMM (NVDIMM), among other devices. A memory system may communicate with a host system, which may include a host system controller. The host system may be implemented using one or more processors and a memory system for writing data to the memory system, reading data from the memory system, erasing data, or refreshing data.

A memory system may include one or more memory devices, such as device 130. A memory device 130 may include one or more memory arrays of any type of memory cells (e.g., non-volatile memory cells, volatile memory cells, or any combination thereof). For example, memory device 130 may include NAND (e.g., NAND flash) memory, ROM, phase change memory (PCM), NOR (e.g., NOR flash) memory, etc. In some cases, memory device 130 is a NAND memory device 130, may include memory cells configured to each store one bit of information, which may be referred to as single level cells (SLCs). Additionally, or alternatively, a NAND memory device 130 may include memory cells configured to each store multiple bits of information, which may be referred to as multi-level cells (MLCs) if configured to each store two bits of information, as tri-level cells (TLCs) if configured to each store three bits of information, as quad-level cells (QLCs) if configured to each store four bits of information, or more generically as multiple-level memory cells. Multiple-level memory cells may provide greater density of storage relative to SLC memory cells but may, in some cases, involve narrower read or write margins or greater complexities for supporting circuitry.

As shown in FIG. 1 and described below in more detail, memory device 130 includes an array of memory cells 104 logically arranged in rows and columns. Memory cells of a logical row are typically connected to the same access line (e.g., a word line) while memory cells of a logical column are typically selectively connected to the same data line (e.g., a bit line). A single access line can be associated with more than one logical row of memory cells and a single data line can be associated with more than one logical column. Memory cells (not shown in FIG. 1) of at least a portion of the array of memory cells 104 are capable of being programmed to one of at least two target data states for storing any number of bits of information.

With continued reference to FIG. 1, row decode circuitry 108 and column decode circuitry 111 are provided to decode address signals. Address signals are received and decoded to access the array of memory cells 104. Memory device 130 also includes input/output (I/O) control circuitry 112 to manage input of commands, addresses, and data to memory device 130 as well as output of data and status information from memory device 130. An address register 114 is in communication with I/O control circuitry 112 and row decode circuitry 108 and column decode circuitry 111 to latch the address signals prior to decoding. Row decode circuitry 108 and column decode circuitry 111 may simply be referred to as row decoder 108 and column decoder 111, respectively. A command register 124 is in communication with the I/O control circuitry 112 and local controller 135 to latch incoming commands.

A memory controller (e.g., the local controller 135 internal to memory device 130) controls access to the array of memory cells 104 in response to the commands and generates status information for the external system controller 115. For example, the local controller 135, on its own or in response to a command provided by external system controller 115, is configured to perform access operations (e.g., read operations, programming operations, and/or erase operations) on the array of memory cells 104. The local controller 135 is in communication with row decode circuitry 108 and column decode circuitry 111 to control the row decode circuitry 108 and column decode circuitry 111 according to the addresses.

In some embodiments, local controller 135 communicates with the external system controller 115, which may be a host controller (e.g., an UFS or eMMC controller, or a CPU communicating with local controller 135) located in a host system or a memory system controller located in a memory system. In some embodiments, local controller 135 is disposed on the same semiconductor die as the memory array (e.g., array 104), and a separate system controller 115 is disposed on a different die. In other examples, some portions of memory device 130 may be disposed on a first die and other portions of memory device 130 may be disposed on a second die different from the first die. For instance, the first die may include the array of memory cells 104 and its associated circuitry such as the column decoder 111 and row decoder 108, etc. The second die may include logic circuitry, power circuitry, or other circuitry of device 130. Thus, the second die may include system controller 115, I/O control 112, etc. In this example, the first die has no local controller, and the second die includes the system controller 115. The first die and the second die can be hybrid bonded together using, for example, through-hole vias (TSVs) such that they are electrically connected. The first die and the second die may also be wafer-bonded using flip-chip bonding technologies, etc. In this disclosure, a system controller 115 and a local controller 135 may both be referred to as memory controllers, or a first memory controller and a second memory controller, for simplicity. It is understood that while they may be different controllers, certain operations disclosed herein may be caused or performed by either or both memory controllers, unless otherwise specified. In the present disclosure, the operations performed by the controller may be performed via control logic included in the controller. The control logic may include control circuitry and/or other hardware or software that may be used to perform the operations of the controller.

Local controller 135 is also in communication with a cache register 118 and a data register 121. In some embodiments, one or more cache registers 118 can collectively form at least a part of a cache buffer. Cache register 118 latches or buffers data, either incoming or outgoing, as directed by local controller 135 to temporarily store data while the array of memory cells 104 is busy writing or reading, respectively, other data. During a program operation (e.g., write operation), data can be passed from cache register 118 to the data register 121 for transfer to the array of memory cells 104; then new data can be latched in cache register 118 from the I/O control circuitry 112. During a read operation, data can be passed from the cache register 118 to the I/O control circuitry 112 for output to the system controller 115; then new data can be passed from the data register 121 to cache register 118. In some embodiments, cache register 118 and/or the data register 121 can form at least a portion of a page buffer 152 of the memory device 130. The page buffer 152 can further include sensing devices such as a sense amplifier, to sense a data state of a memory cell of the array of memory cells 104, e.g., by sensing a state of a data line connected to that memory cell. A status register 122 can be in communication with I/O control circuitry 112 and the local memory controller 135 to latch the status information for output to system controller 115.

As shown in FIG. 1, memory device 130 receives various control signals via local controller 135 from system controller 115 over a control link 132. For example, the control signals can include a chip enable signal CE#, a command latch enable signal CLE, an address latch enable signal ALE, a write enable signal WE#, a read enable signal RE#, and a write protect signal WP#. Additional or alternative control signals (not shown) can be further received over control link 132 depending upon the nature of memory device 130. In one embodiment, memory device 130 receives command signals (which represent commands), address signals (which represent addresses), and data signals (which represent data) from the system controller 115 over a multiplexed input/output (I/O) bus 134 and outputs data to the system controller 115 over I/O bus 134.

For example, the commands can be received over input/output (I/O) pins [7:0] of I/O bus 134 at I/O control circuitry 112 and can then be written into a command register 124. The addresses can be received over input/output (I/O) pins [7:0] of I/O bus 134 at I/O control circuitry 112 and can then be written into address register 114. The data can be received over input/output (I/O) pins [7:0] for an 8-bit device or input/output (I/O) pins [15:0] for a 16-bit device at I/O control circuitry 112 and then can be written into cache register 118. The data can be subsequently written into data register 121 for programming the array of memory cells 104.

In an embodiment, cache register 118 can be omitted, and the data can be written directly into data register 121. Data can also be output over input/output (I/O) pins [7:0] for an 8-bit device or input/output (I/O) pins [15:0] for a 16-bit device. Although reference can be made to I/O pins, they can include any conductive node providing for electrical connection to the memory device 130 by an external device (e.g., the system controller 115), such as conductive pads or conductive bumps as are commonly used. While the above description using 16 bits I/O bus 134 as an example, it is understood that bus 134 can be configured to any number of bits (e.g., 64 bits).

It will be appreciated by those skilled in the art that additional circuitry and signals can be provided, and that memory device 130 of FIG. 1 has been simplified. It should be recognized that the functionality of the various block components described with reference to FIG. 1 may not necessarily be segregated to distinct components or component portions of an integrated circuit device. For example, a single component or component portion of an integrated circuit device could be adapted to perform the functionality of more than one block component of FIG. 1. Alternatively, one or more components or component portions of an integrated circuit device could be combined to perform the functionality of a single block component of FIG. 1. Additionally, while specific I/O pins are described in accordance with popular conventions for receipt and output of the various signals, it is noted that other combinations or numbers of I/O pins (or other I/O node structures) can be used in the various embodiments.

In some cases, the local controller 135 may be configured to regulate different voltages used with respect to different operations of the NAND memory device 130. For example, the local controller 135 may be configured to cause generation and/or routing of different voltage levels to different components of the NAND memory device 130 based on the type of operations being performed by the NAND memory device 130. For example, in some embodiments, the NAND memory device 130 may be configured to receive multiple supply voltages with varying voltage levels and multiple programming power voltages with varying voltage levels from external power circuitry. For example, the NAND memory device 130 may include internal power circuitry 160 configured to receive the multiple supply voltages and/or multiple programming power voltages. The internal power circuitry 160 may be configured to obtain the multiple supply voltages and/or multiple programming power voltages from external power circuitry 164. The external power circuitry 164 may be a part of a system utilizing the NAND memory device 130. For example, the external power circuitry 164 may be a part of a SSD utilizing the NAND memory device 130. The external power circuitry 164 may be configured to generate the multiple supply voltages and/or the multiple programming power voltages based at least on power received from a power source 162. The power source 162 may be an external power source (e.g., outside of the SSD). In some embodiments, the power circuitry 164 may be configured to provide the multiple supply voltages and/or the multiple programming power voltages to multiple memory devices including the NAND memory device 130. In other embodiments, the power circuitry 164 may be configured to provide the voltages to the NAND memory device 130 individually. In these and other embodiments, the local controller 135 may be configured to apply the varying voltage levels (e.g., the supply voltages and the programming power voltages) for different operations.

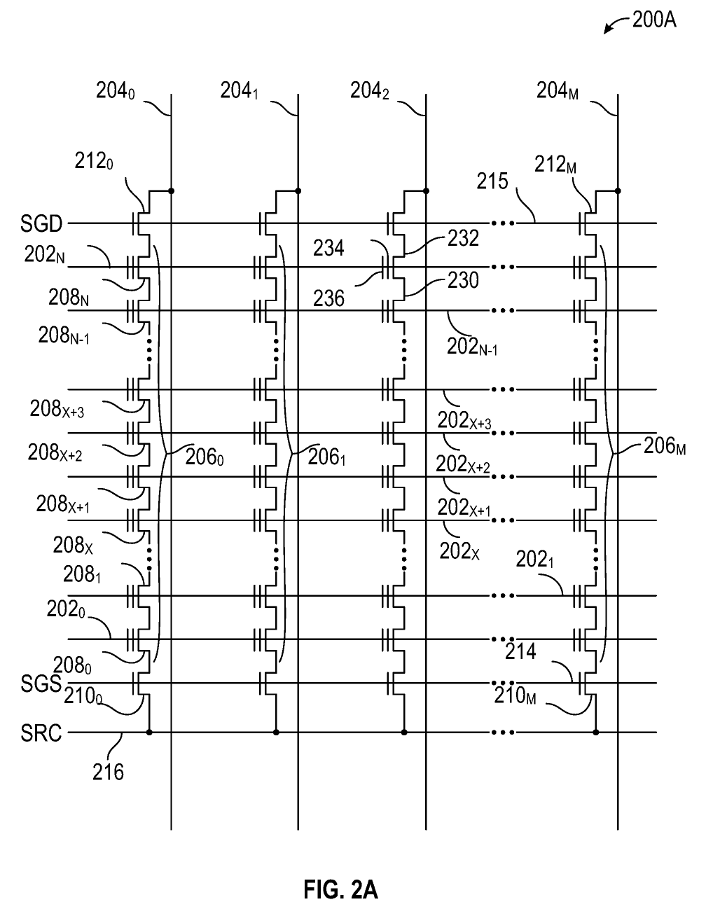

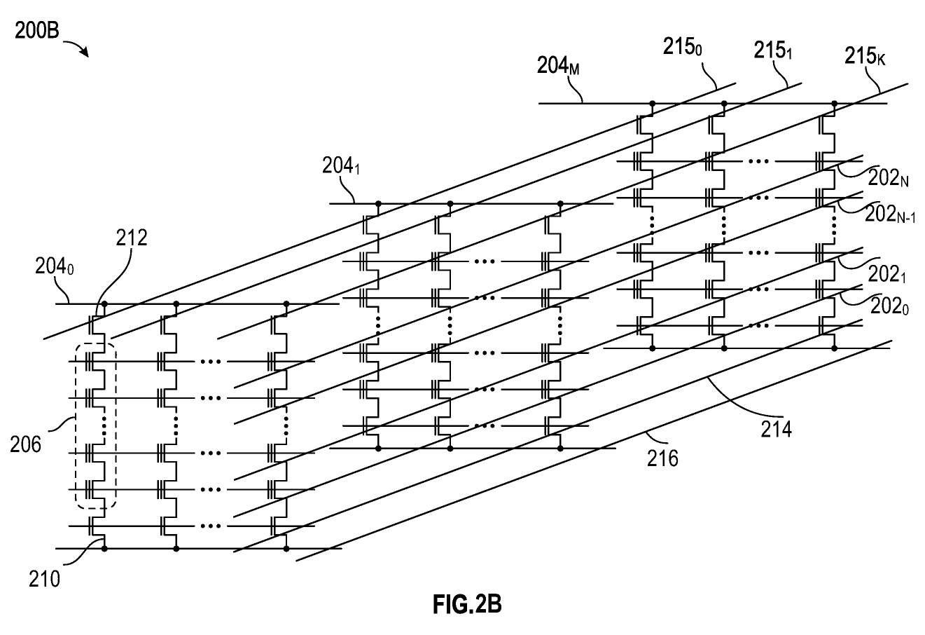

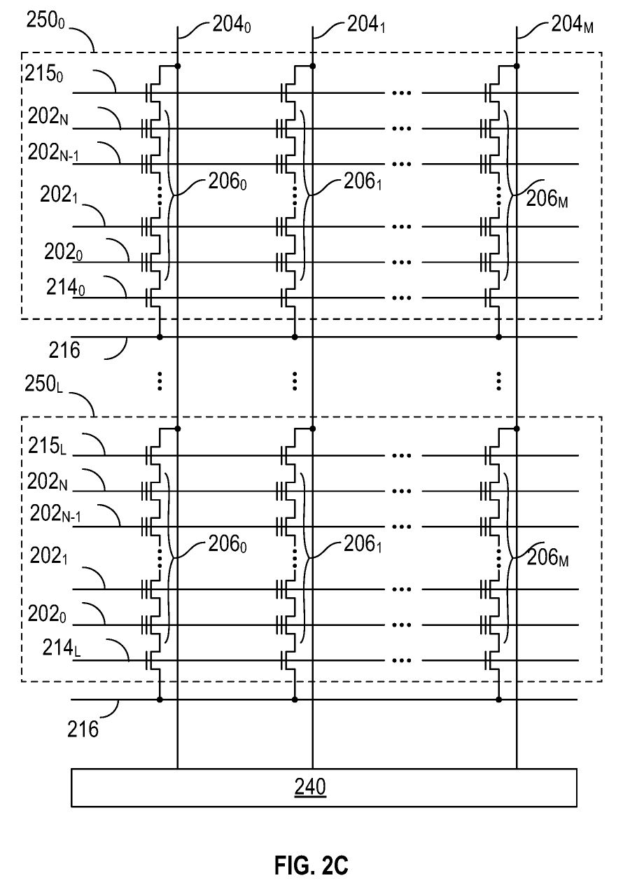

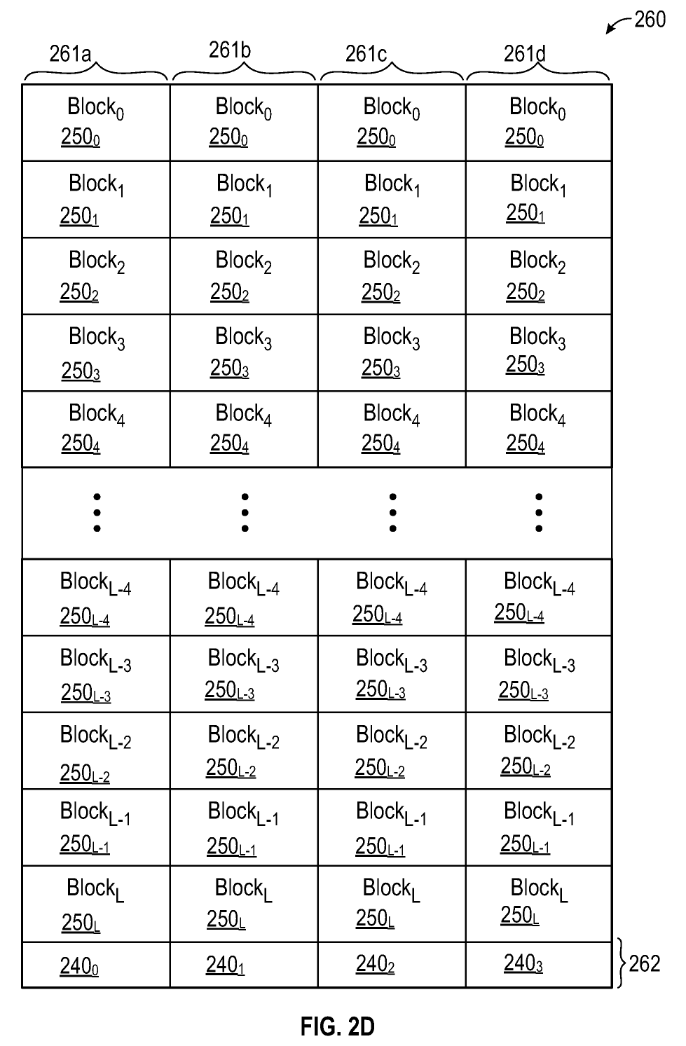

FIGS. 2A-2B are example schematics of portions of an array of memory cells 200A, such as a NAND memory array. Array of memory cells 200A may be an example of memory array 104 of a memory device 130 as described with reference to FIG. 1 according to an embodiment. Memory array 200A includes access lines, such as word lines 202₀to 202_{N}, and data lines, such as bit lines 204₀to 204_{M}. The word lines 202 can be connected to global access lines (e.g., global word lines), not shown in FIG. 2A, in a many-to-one relationship. For some embodiments, memory array 200A can be formed over a semiconductor that, for example, can be doped to have a conductive type, such as a p-type conductivity, e.g., to form a p-well, or an n-type conductivity, e.g., to form an n-well.

Memory array 200A can be arranged in rows (each corresponding to a word line 202) and columns (each corresponding to a bit line 204). Each column can include a string of series-connected memory cells (e.g., non-volatile memory cells), such as one of NAND strings 206₀to 206_{M}. Each NAND string 206 can be connected (e.g., selectively connected) to a common source (SRC) 216 and can include memory cells 208₀to 208_{N}. The memory cells 208 can represent non-volatile memory cells for storage of data. The memory cells 208 of each NAND string 206 can be connected in series between a select transistor 210 (e.g., a field-effect transistor), such as one of the select gates 210₀to 210_{M} (e.g., that can be source select transistors, commonly referred to as select gate source), and a select transistor 212 (e.g., a field-effect transistor), such as one of the select transistors 212₀to 212_{M} (e.g., that can be drain select transistors, commonly referred to as select gate drain). Select gates 210₀to 210_{M} can be commonly connected to a select line 214, such as a source select line (SGS), and select gates 212₀to 212_{M} can be commonly connected to a select line 215, such as a drain select line (SGD). Although depicted as traditional field-effect transistors, the select transistors 210 and 212 can utilize a structure similar to (e.g., the same as) the memory cells 208. The select transistors 210 and 212 can represent a number of select gates connected in series, with each select transistor in series configured to receive a same or independent control signal.

A source of each select transistor 210 can be connected to common source 216. The drain of each select transistor 210 can be connected to a memory cell 208₀of the corresponding NAND string 206. For example, the drain of select gate 210₀can be connected to memory cell 208₀of the corresponding NAND string 206₀. Therefore, each select transistor 210 can be configured to selectively connect a corresponding NAND string 206 to the common source 216. A control gate of each select transistor 210 can be connected to select line 214.

The drain of each select transistor 212 can be connected to bit line 204 for the corresponding NAND string 206. For example, the drain of select gate 212₀can be connected to the bit line 204₀for the corresponding NAND string 206₀. The source of each select transistor 212 can be connected to a memory cell 208_{N} of the corresponding NAND string 206. For example, the source of select gate 212₀can be connected to memory cell 208_{N} of the corresponding NAND string 206₀. Therefore, each select transistor 212 can be configured to selectively connect a corresponding NAND string 206 to the corresponding bit line 204. A control gate of each select transistor 212 can be connected to select line 215.

The memory array 200A in FIG. 2A can be a quasi-two-dimensional memory array and can have a generally planar structure, e.g., where the common source 216, NAND strings 206 and bit lines 204 extend in substantially parallel planes. Alternatively, the memory array 200A in FIG. 2A can be a three-dimensional memory array, e.g., where NAND strings 206 can extend substantially perpendicular to a plane containing the common source 216 and to a plane containing the bit lines 204 that can be substantially parallel to the plane containing the common source 216.

Typical construction of memory cells 208 includes a data-storage structure 234 (e.g., a charge trap, and the like) that can determine a data state of the memory cell (e.g., through changes in threshold voltage), and a control gate 236, as shown in FIG. 2A. The data-storage structure 234 can include both conductive and dielectric structures while the control gate 236 is generally formed of one or more conductive materials. In some cases, memory cells 208 can further have a defined source/drain (e.g., source) 230 and a defined source/drain (e.g., drain) 232. Memory cells 208 have their control gates 236 connected to (and in some cases form) a word line 202.

A column of the memory cells 208 can be a NAND string 206 or a number of NAND strings 206 selectively connected to a given bit line 204. A row of memory cells 208 can be memory cells 208 commonly connected to a given word line 202. A row of memory cells 208 can, but need not, include all the memory cells 208 commonly connected to a given word line 202. Rows of memory cells 208 can often be divided into one or more groups of physical pages of memory cells 208, and physical pages of the memory cells 208 often include every other memory cell 208 commonly connected to a given word line 202. For example, the memory cells 208 commonly connected to word line 202_{N} and selectively connected to even bit lines 204 (e.g., bit lines 204₀, 204₂, 204₄, etc.) can be one physical page of the memory cells 208 (e.g., even memory cells) while memory cells 208 commonly connected to word line 202_{N} and selectively connected to odd bit lines 204 (e.g., bit lines 204₁, 204₃, 204₅, etc.) can be another physical page of the memory cells 208 (e.g., odd memory cells).

Although bit lines 204₃-204₅are not explicitly depicted in FIG. 2A, it is apparent from the figure that the bit lines 204 of the array of memory cells 200A can be numbered consecutively from bit line 204₀to bit line 204_{M}. Other groupings of memory cells 208 commonly connected to a given word line 202 can also define a physical page of memory cells 208. For certain memory devices, all memory cells commonly connected to a given word line can be deemed a physical page of memory cells. The portion of a physical page of memory cells (which, in some embodiments, could still be the entire row) that is read during a single read operation or programmed during a single programming operation (e.g., an upper or lower page of memory cells) can be deemed a logical page of memory cells. A block of memory cells can include those memory cells that are configured to be erased together, such as all memory cells connected to word lines 202₀-202_{N} (e.g., all NAND strings 206 sharing common word lines 202). Unless expressly distinguished, a reference to a page of memory cells herein refers to the memory cells of a logical page of memory cells. A logical page may or may not be the same as a physical page. Although the example of FIG. 2A is discussed in conjunction with NAND flash, the embodiments and concepts described herein are not limited to a particular array architecture or structure, and can include other structures (e.g., SONOS, phase change, ferroelectric, etc.) and other architectures (e.g., AND arrays, NOR arrays, etc.).

FIG. 2B is another schematic of a portion of an array of memory cells 200B as could be used in a memory device 130, e.g., as a portion of the array of memory cells 104. Like numbered elements in FIG. 2B correspond to the description as provided with respect to FIG. 2A. FIG. 2B provides additional detail of one example of a three-dimensional NAND memory array structure. Three-dimensional NAND memory array 200B can incorporate vertical structures which can include semiconductor pillars where a portion of a pillar can act as a channel region of the memory cells of NAND strings 206. NAND strings 206 can be each selectively connected to a bit line 204₀-204_{M} by a select transistor 212 (e.g., that can be drain select transistors, commonly referred to as select gate drain) and to a common source 216 by a select transistor 210 (e.g., that can be source select transistors, commonly referred to as select gate source). Multiple NAND strings 206 can be selectively connected to the same bit line 204. Subsets of NAND strings 206 can be connected to their respective bit lines 204 by biasing the select lines 215₀-215_{K} to selectively activate particular select transistors 212 each between a NAND string 206 and a bit line 204. The select transistors 210 can be activated by biasing the select line 214. In some embodiments, each sub-block or string of memory cells has a separate select line 214 from other sub-blocks or strings. In some embodiments, a pair of sub-blocks shares a select line 214. Each word line 202 can be connected to multiple rows of memory cells of the memory array 200B. Rows of memory cells that are commonly connected to each other by a particular word line 202 can collectively be referred to as tiers.

The three-dimensional NAND memory array 200B may include multiple stacked layers of levels of memory cells and connected using vertical channels such as semiconductor pillars. The number of layers in three-dimensional NAND memory array 200B can be, for example, 32, 48, 64, 96, 112 layers, or any number of layers. In some examples, a group of layers may be collectively referred to as a deck. A deck in a three-dimensional NAND memory array may be processed together (e.g., etched together for forming a portion of the semiconductor pillar). A memory device having three-dimensional NAND memory arrays can provide more memory cells on a single chip than a memory device formed by two-dimensional NAND arrays; and therefore provide a higher storage capacity. Furthermore, in a memory device having three-dimensional NAND memory arrays, transistors in memory cells are spaced out, and therefore interference and electron leaks can be reduced.

In some examples, memory cells can be grouped into memory blocks. FIG. 2C depicts groupings of NAND strings 206 into blocks of memory cells 250, e.g., blocks of memory cells 250₀-250_{L}. Blocks of memory cells 250 can be groupings of memory cells 208 that can be erased together in a single erase operation. The group of memory cells that can be erased together is also referred to as an erase block. Each block of memory cells 250 can represent those NAND strings 206 commonly associated with a single select line 215, e.g., select line 215₀. The common source 216 for the block of memory cells 250₀can be a same source as the source 216 for the block of memory cells 250_{L}. For example, each block of memory cells 250₀-250_{L} can be commonly selectively connected to the source 216. Access lines 202 and select lines 214 and 215 of one block of memory cells 250 can have no direct connection to access lines 202 and select lines 214 and 215, respectively, of any other block of memory cells of the blocks of memory cells 250₀-250_{L}.

The bit lines 204₀-204_{M} can be connected (e.g., selectively connected) to a buffer portion 240, which can be a portion of the page buffer 152 of the memory device 130. The buffer portion 240 can correspond to a memory plane (e.g., the set of blocks of memory cells 250₀-250_{L}). The buffer portion 240 can include sense circuits (which can include sense amplifiers) for sensing data values indicated on respective bit lines 204. In one example, buffer portion 240 can be a part of page buffer 152. As described below, multiple buffer portions 240 may collectively form a page buffer 152.

FIG. 2D is a block schematic of a portion of an example array of memory cells 260. Array of memory cells 260 can be used as the memory array 104 in a memory device 130. The array of memory cells 260 is depicted as having four memory planes 261 (e.g., memory planes 261a-261d). Each of the memory planes 261 may refer to a group of memory blocks of memory cells 250. Each memory plane 261 can be in communication with a respective buffer portion 240, which can collectively form a page buffer 262. Page buffer 262 may be used to implement page buffer 152 shown in FIG. 1. While four memory planes 261 are depicted, other numbers of memory planes 261 can be commonly in communication with a page buffer 262. Each memory plane 261 is depicted to include L+1 blocks of memory cells 250 (e.g., blocks of memory cells 250₀-250_{L}).

In some cases, concurrent operations may be performed on different planes. For example, concurrent operations may be performed on memory cells within different blocks so long as the different blocks are in different planes 261. In some cases, an individual memory block may be referred to as a physical block, and a virtual block may refer to a group of blocks within which concurrent operations may occur. For example, concurrent operations may be performed on four blocks of 250₀that are within planes 261a, 261b, 261c, and 261d, respectively, and the four blocks of 250₀may be collectively referred to as a virtual block. In some cases, a virtual block may include blocks from different memory devices. In some cases, the physical blocks within a virtual block may have the same block address within their respective planes. In some cases, performing concurrent operations in different planes 261 may be subject to one or more restrictions, such as concurrent operations being performed on memory cells within different pages that have the same page address within their respective planes 261 (e.g., related to command decoding, page address decoding circuitry, or other circuitry being shared across planes 261).

In some cases, a block may include memory cells organized into rows (pages) and columns (e.g., strings, not shown). For example, memory cells in a same page may share (e.g., be coupled with) a common word line, and memory cells in a same string may share (e.g., be coupled with) a common digit line (which may alternatively be referred to as a bit line).

For some NAND architectures, memory cells may be read and programmed (e.g., written) at a first level of granularity (e.g., at a page level of granularity, or portion thereof) but may be erased at a second level of granularity (e.g., at a block level of granularity). That is, a page may be the smallest unit of memory (e.g., set of memory cells) that may be independently programmed or read (e.g., programed or read concurrently as part of a single program or read operation), and a memory block 170 may be the smallest unit of memory (e.g., set of memory cells) that may be independently erased (e.g., erased concurrently as part of a single erase operation). Further, in some cases, NAND memory cells may be erased before they can be re-written with new data. Thus, for example, a used page may, in some cases, not be updated until the entire block that includes the page has been erased.

With continued reference to FIGS. 1 and 2A-2C, during a true erase operation (during which memory cells are actually being erased), the local controller 135 (e.g., using an erase operation manager 137) can cause a common source voltage line, e.g., the SRC 216 (FIG. 2A), to be ramped to an erase voltage (Vera) with an erase pulse while the select gates 210₀to 210_{M} (SGS transistors) are turned on. Ramping to this high bias erase voltage, and the subsequent recovery from this voltage ramping, may take a significant amount of time. Concurrently, the erase operation manager 137 can cause the select gates 212₀to 212ₘ (FIG. 2A) to be turned off to enable the drains of the select gates 212₀to 212ₘ to float, which causes the bit lines 204₀to 204_{M} to also float. Further, the erase operation manager 137 can couple the word lines 202 (FIG. 2A) to ground, e.g., zero volts, or retain the word lines 202 at a low voltage. This set of voltage levels at the memory array 200A can create an erase potential that causes the memory cells 208₀to 208_{N} to be erased, e.g., forces electrons to exit through a body of each memory cell and out the floating bit lines 204₀to 204_{M}. In other embodiments, the reverse can be done so the select gates 210₀to 210_{M} are turned off, causing the SRC line 216 to float while the voltages of the bit lines are ramped to Vera while the select gates 212₀to 212_{M} are turned on. As mentioned earlier, in 3D NAND, one of the channel region, pillar, or bit line can also be ramped up in voltage to cause erasure of attached memory cells. Thus, for simplicity herein, reference to "memory line" should be understood to make reference to any of the SRC line or bit lines in 2D NAND or to any of channel, pillar, or bit lines in 3D NAND. In some embodiments, one or more sub-blocks, to include a physical block, of memory cells are erased during the same true erase operation. A block of memory cells can be generally understood to include four or more sub-blocks, wherein each sub-block includes a separate string of memory cells.

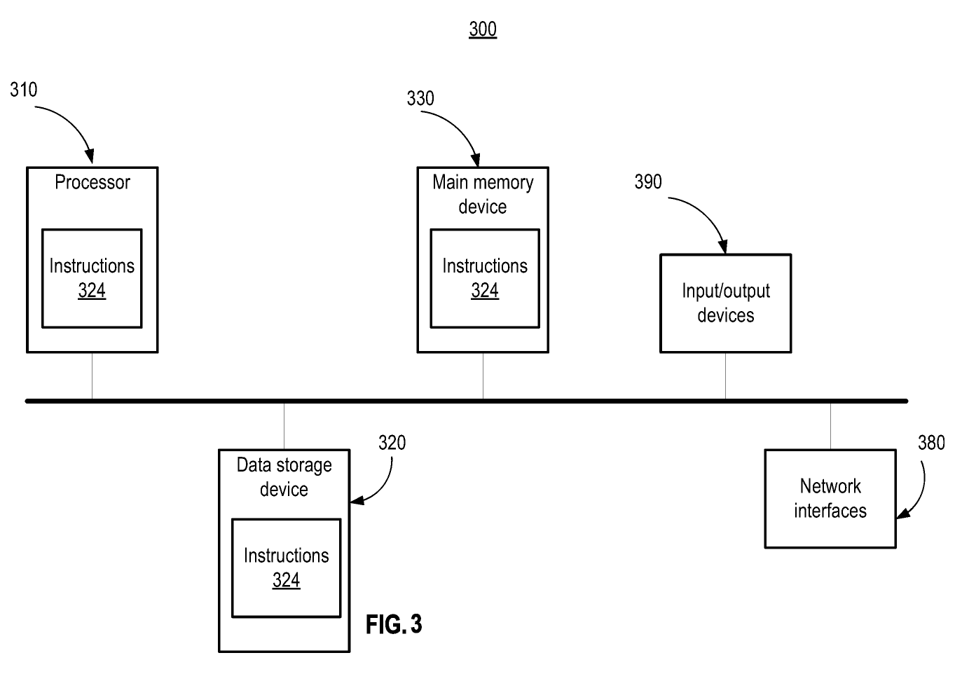

A high-level block diagram of an example apparatus 300 that may be used to implement systems, apparatus, and methods described herein is illustrated in FIG. 3. It is understood that various systems, apparatus, and methods described herein may be implemented using analog and/or digital circuitry, or using one or more computers using well-known computer processors, memory systems, storage devices, computer software, and other components. Typically, a computer includes a processor for executing instructions and one or more memory systems for storing instructions and data. A computer may also include, or be coupled to, one or more mass storage devices, such as one or more magnetic disks, internal hard disks and removable disks, magneto-optical disks, optical disks, etc.

Various systems, apparatus, and methods described herein may be implemented using computers operating in a client-server relationship. Typically, in such a system, the client computers are located remotely from the server computers and interact via a network. The client-server relationship may be defined and controlled by computer programs running on the respective client and server computers. Examples of client computers can include desktop computers, workstations, portable computers, cellular smartphones, tablets, or other types of computing devices.

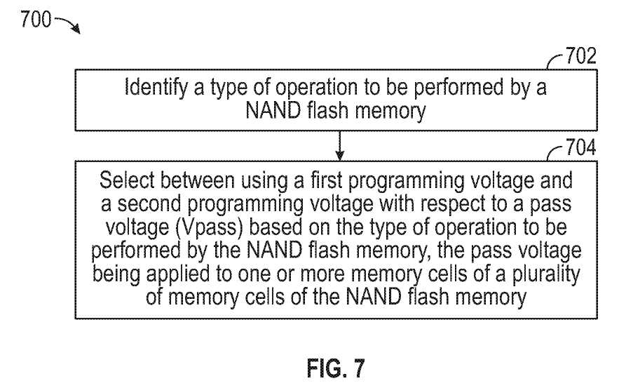

Various systems, apparatus, and methods described herein may be implemented using a computer program product tangibly embodied in an information carrier, e.g., in a non-transitory machine-readable storage device, for execution by a programmable processor; and the method processes and steps described herein, including one or more of the steps of FIG. 7, may be implemented using one or more computer programs that are executable by such a processor. A computer program is a set of computer program instructions that can be used, directly or indirectly, in a computer to perform a certain activity or bring about a certain result. A computer program can be written in any form of programming language, including compiled or interpreted languages, and it can be deployed in any form, including as a stand-alone program or as a module, component, subroutine, or other unit suitable for use in a computing environment.

As shown in FIG. 3, apparatus 300 may be used to implement a host system that includes, is coupled to, or utilizes a memory system (e.g., memory system shown in FIG. 1). Apparatus 300 can be used to perform operations of a controller (e.g., to execute an operating system to perform operations corresponding to system controller 115 and/or local controller 135 of FIG. 1).

In some embodiments, apparatus 300 comprises a processor 310 operatively coupled to a data storage device 320 and a main memory device 330. Processor 310 controls the overall operation of apparatus 300 by executing computer program instructions 324 that define such operations. The instructions 324 include instructions to implement functionality of a controller (e.g., system controller 115 and/or local controller 135 of FIG. 1). The computer program instructions 324 may be stored in data storage device 320, or other computer-readable medium, and loaded into main memory device 330 when execution of the computer program instructions is desired. For example, processor 310 may be used to implement one or more components and systems described herein, such as system controller 115 and/or local controller 135 (shown in FIG. 1). Thus, the method steps of at least some of FIG. 7 can be defined by the computer program instructions 324 stored in main memory device 330 and/or data storage device 320 and controlled by processor 310 executing the computer program instructions 324. For example, the computer program instructions 324 can be implemented as computer executable code programmed by one skilled in the art to perform an algorithm defined by the method steps discussed herein in connection with at least some of FIG. 7. Accordingly, by executing the computer program instructions, processor 310 executes an algorithm defined by the method steps of these aforementioned figures to perform operations (e.g., read, program, erase, etc.). Apparatus 300 also includes one or more network interfaces 380 for communicating with other devices via a network. Apparatus 300 may also include one or more input/output devices 390 that enable user interaction with apparatus 300 (e.g., display, keyboard, mouse, speakers, buttons, etc.).

Processor 310 may include both general and special purpose microprocessors and may be the sole processor or one of multiple processors of apparatus 300. Processor 310 may comprise one or more central processing units (CPUs), and one or more graphics processing units (GPUs), which, for example, may work separately from and/or multi-task with one or more CPUs to accelerate processing, e.g., for various image processing applications described herein. Processor 310, data storage device 320, and/or main memory device 330 may include, be supplemented by, or incorporated in, one or more application-specific integrated circuits (ASICs) and/or one or more field programmable gate arrays (FPGAs).

Data storage device 320 and main memory device 330 each comprise a tangible non-transitory computer readable storage medium. Data storage device 320, and main memory device 330, may each include high-speed random access memory, such as dynamic random access memory (DRAM), static random access memory (SRAM), double data rate synchronous dynamic random access memory (DDR RAM), or other random access solid state memory devices, and may include non-volatile memory, such as one or more magnetic disk storage devices such as internal hard disks and removable disks, magneto-optical disk storage devices, optical disk storage devices, flash memory devices (NAND memory devices, NOR memory devices), semiconductor memory devices, such as erasable programmable read-only memory (EPROM), electrically erasable programmable read-only memory (EEPROM), compact disc read-only memory (CD-ROM), digital versatile disc read-only memory (DVD-ROM) disks, or other non-volatile solid state storage devices. For example, data storage device 320 may be implemented using the memory system (e.g., system shown in FIG. 1) described herein. In some examples, data storage device 320 and main memory device 330 may include one or more memory devices 130 (FIG. 1).

Input/output devices 390 may include peripherals, such as a printer, scanner, display screen, etc. For example, input/output devices 390 may include a display device such as a cathode ray tube (CRT), plasma or liquid crystal display (LCD) monitor for displaying information to a user, a keyboard, and a pointing device such as a mouse or a trackball by which the user can provide input to apparatus 300.

Any or all of the functions of the systems and apparatuses discussed herein may be performed by processor 310, and/or incorporated in, an apparatus or a system such as system 100. Further, system 100 and/or apparatus 300 may utilize one or more neural networks or other deep-learning techniques performed by processor 310 or other systems or apparatuses discussed herein.

One skilled in the art will recognize that an implementation of an actual computer or computer system may have other structures and may contain other components as well, and that FIG. 3 is a high-level representation of some of the components of such a computer for illustrative purposes.

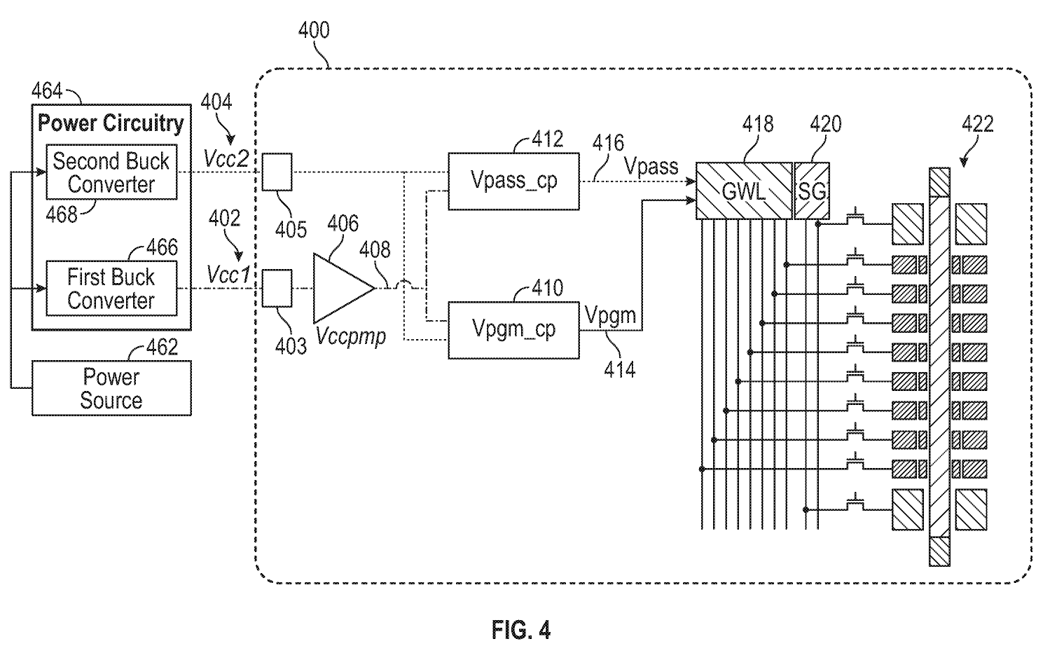

FIG. 4 illustrates example components of a NAND memory device 400 (hereinafter referred to as NAND memory 400) related to implementing power supply differentiation, in accordance with examples as disclosed herein. The NAND memory 400 is configured to obtain multiple supply voltages via multiple voltage pads corresponding to the multiple supply voltages. The multiple supply voltages include varying voltage levels configured for different purposes. For example, the NAND memory 400 may implement power supply management such that energy demands of different operations may be met with increased performance and efficiency. For instance, the varying supply voltages may allow the NAND memory 400 to provide different voltages with reduced stages of voltage regulators within the NAND memory 400. In some embodiments, the NAND memory 400 may correspond to the memory device 130 of FIG. 1. In these and other embodiments, the NAND memory 400 may include a controller, such as, for example, the local controller 135 of FIG. 1, configured to manage the multiple supply voltages.

With reference back to FIG. 4, in some embodiments, the NAND memory 400 may be configured to receive a first supply voltage 402 (denoted by Vcc1) and a second supply voltage 404 (denoted by Vcc2). In some embodiments, the first supply voltage 402 may be a common or general supply voltage. In these and other embodiments, the second supply voltage 404 may include a high Vcc. In these and other embodiments, the second supply voltage 404 may be or include voltage levels higher than the first supply voltage 402.

In some embodiments, the NAND memory 400 may include voltage pads corresponding to the multiple supply voltages. For example, the NAND memory 400 may include a first supply voltage pad 403 configured to receive the first supply voltage 402 and a second supply voltage pad 405 configured to receive the second supply voltage 404. In these and other embodiments, the first supply voltage pad 403 and the second supply voltage pad 405 may be separate such that the first supply voltage 402 and the second supply voltage 404 may be received separately without affecting each other. While described with respect to the first supply voltage pad 403 and the second supply voltage pad 405, the NAND memory 400 may include additional number of voltage pads configured to receive additional supply voltages.

In some embodiments, the NAND memory 400 may be configured to receive the first supply voltage 402 and the second supply voltage 404 from external power circuitry 464. In some embodiments, the external power circuitry 464 may be part of a solid-state drive (SSD) configured to use the NAND memory 400. For example, the NAND memory 400 may be implemented as part of the SSD. In these and other embodiments, the external power circuitry 464 may be configured to receive power from external power source and to pass on the power to the NAND memory 400. In some embodiments, the external power circuitry 464 may be configured to generate multiple supply voltages (e.g., the first supply voltage 402 and the second supply voltage 404). In some embodiments, the external power circuitry 464 may correspond to the external power circuity 164 of FIG. 1.

For example, in some embodiments, the external power circuitry 464 may include a first buck converter 466 and a second buck converter 468. The first buck converter may be configured to step down an external voltage to generate the first supply voltage 402, and the second buck converter may be configured to step down the external voltage from a power source 462 to generate the second supply voltage 404. In some embodiments, the first supply voltage 402 may include a voltage within a first range, and the second supply voltage 404 may include a voltage within a second range, in which the second range includes higher voltage than the first range. For example, the first range may range from 2.3V to 3.6V, and the second range may range from 3.6V to 4V. In these and other embodiments, the Second supply voltage 404 may be generated or selected to be higher than the first supply voltage 402. For example, in instances in which the first supply voltage 402 is 2.5V, the second supply voltage 404 may be 4V.

With reference to FIG. 4, in some embodiments, the NAND memory 400 may include one or more charge pumps. In some examples, the NAND memory 400 is similar or analogous to the memory device 130 of FIG. 1, although some of the components of the memory device 130 may not be illustrated for simplicity. In some embodiments, the first supply voltage 402 and/or the second supply voltage 404 may be supplied to the one or more charge pumps to generate amplified voltages. For example, the NAND memory 400 may include a first charge pump 410 and a second charge pump 412. In some embodiments, the first charge pump 410 may correspond to a program charge pump (denoted by Vpgm_cp) configured to provide a program voltage 414 (denoted by Vpgm) to an array of memory cells 411 of the NAND memory 400. Additionally or alternatively, the second charge pump 412 may correspond to a pass voltage 416 (denoted by Vpass) charge pump configured to provide additional voltage for the pass voltage 416 based on the first supply voltage 402 and/or the second supply voltage 404.

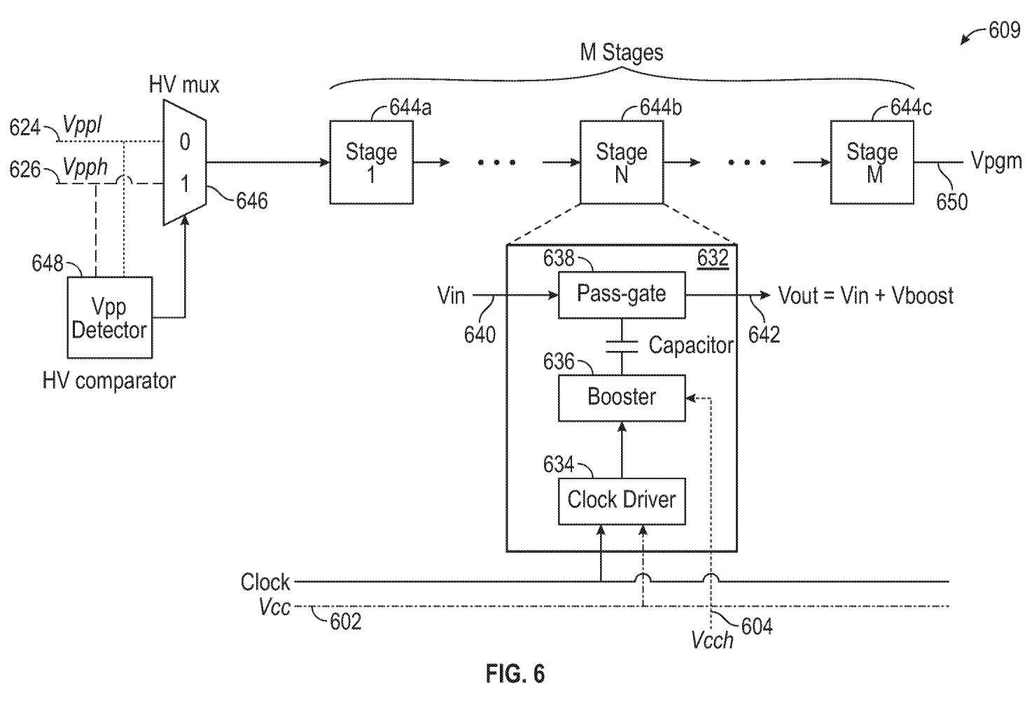

In these and other embodiments, the first supply voltage 402 and the second supply voltage 404 may be provided to the one or more charge pumps to provide power to one or more components of the charge pumps. For example, the first supply voltage 402 may be configured to power a clock of the charge pumps and the second supply voltage 404 may be configured to provide pump voltage used for amplifying voltages input to the charge pumps. For example, the charge pumps may receive programming power voltages which are amplified using the first supply voltage 402 and/or the second supply voltage 404. In some embodiments, the usage of the first supply voltage 402 and the second supply voltage 404 with respect to charge pumps may be described in further detail, for example, with respect to FIG. 6 of the present disclosure.

In some embodiments, the first charge pump 410 and the second charge pump 412 may be configured to respectively provide the program voltage 414 and the pass voltage 416 to global word lines (GWL) 418 of the NAND memory 400. The GWL 418 is a control signal line that connects to local word lines across different layers of blocks in the NAND memory 400. The GWL 418 may allow the local controller to select the row of the memory cells 422 to operate on and to facilitate transfer of the program voltage 414 and/or the pass voltage 416 to the selected rows of the memory cells 422. In some embodiments, the program voltage 414 and the pass voltage 416 may vary based on the type of operations being performed by the NAND memory 400. For example, the program voltage 414 may vary for different operations, such as read solid-state drive (SSD) operation, a write SSD operation, an erase SSD operation, a management operation, etc. In some examples, the NAND memonry 400 may include a select gate (SG) 420 configured to control the connection of the NAND string to the bit line and source line, facilitating data access. The SG 420 may control whether current can enter and exit the NAND string, such that the operations may be performed with respect to the memory cells 422.

For example, certain pass voltage 416 may be applied to the memory cells 422 during the read operation such that the memory cells 422 may pass the current state without affecting the stored data. For example, the pass voltage 416 may be applied to the GWL 418 such that the current state of the cell is passed through the access transistors to sense amplifiers. The pass voltage 416 may be defined to be high enough to pass current through the access transistor to the sense amplifier but not high enough to alter stored data. For example, the pass voltage 416 during a read operation is defined to not be high enough to program or erase the memory. As another example, the program voltage 414 may be applied to the memory cells 422 during the write or programming operation. For example, the program voltage 414 may be applied to the GWL 418 to facilitate the charge trap electron transfer process that transfers charge to charge trap cells of the memory cells 422.

With reference still to FIG. 4, in some embodiments, the NAND memory 400 may include a supply voltage pump 406 (denoted by Vccpmp). The supply voltage pump 406 may be configured to stabilize the first supply voltage 402 to a particular voltage. For example, the supply voltage pump 406 may be configured to stabilize the first supply voltage 402 to 2.3V. In some embodiments, the supply voltage pump 406 may stabilize the first supply voltage 402 to any other suitable voltages. For example, the first supply voltage 402 may be stabilized to any voltage within a range between 2.3V to 3.6V. In these and other embodiments, stabilizing the first supply voltage 402 may help improve optimization with respect to the first supply voltage 402. For example, in instances that first supply voltage 402 fluctuates, the efficiency of different components such as power converters and voltage regulators may decrease. For example, fluctuating supply voltage may lead to higher switching losses for power converters.

Modifications, additions, or omissions may be made to FIG. 4 without departing from the scope of the present disclosure. For example, the NAND memory 400 may include more or fewer elements than those illustrated and described in the present disclosure.

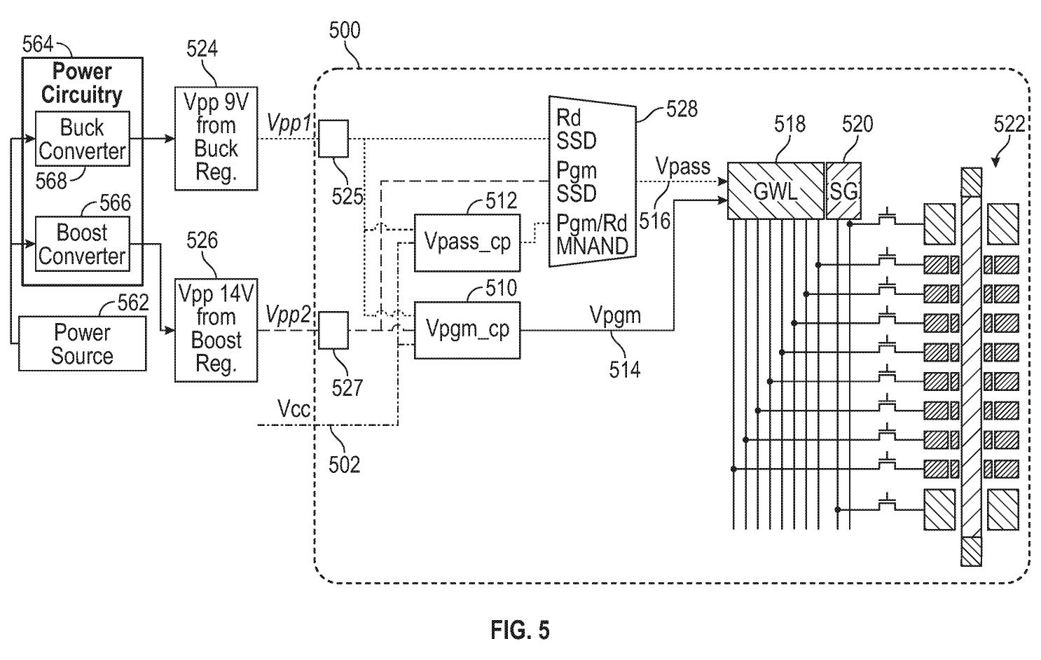

FIG. 5 illustrates another embodiment of a NAND memory 500, in accordance with examples as disclosed herein. In some examples, the NAND memory 500 is similar or analogous to the memory device 130 of FIG. 1 and/or the NAND memory 400 of FIG. 4, although some of the components of the memory device 130 may not be illustrated for simplicity. In some embodiments, the NAND memory 500 may be configured to operate using multiple programming power voltages (Vpps). In some embodiments, the NAND memory 500 may be configured to receive multiple Vpps along with the multiple supply voltages (e.g., the first supply voltage 402 and the second supply voltage 404 of FIG. 4). In these or other embodiments, the NAND memory 500 may be configured to operate using a single supply voltage 502. For example, the NAND memory 500 may operate using the first supply voltage 402 corresponding to the single supply voltage 502 without the second supply voltage 404.

In some embodiments, the NAND memory 400 may be configured to receive a first Vpp 524 and a second Vpp 526. In some embodiments, the NAND memory 400 may have separate voltage pads corresponding to the first Vpp 524 and the second Vpp 526. For example, the NAND memory 500 may include a first Vpp pad 525 configured to receive the first Vpp 524 and a second Vpp pad 527 configured to receive the second Vpp 526. In some embodiments, the NAND memory 500 may receive the first Vpp 524 and the second Vpp 526 via external power circuitry. In some embodiments, the external power circuitry may be a part of an SSD implementing the NAND memory 500. In some embodiments, the external power circuitry may be the same external power circuitry configured to generate the first supply voltage 402 and the second supply voltage 404. In some embodiments, the external power circuitry generating the first Vpp 524 and the second Vpp 526 may be separate from the external power circuitry generating the first supply voltage 402 and/or the second supply voltage 404.

In some embodiments, the external power circuitry may include a buck (step-down) converter configured to generate the first Vpp 524. For example, the buck converter may step down a DC voltage from an external power source to a certain voltage level for the first Vpp 524. The external power circuitry may further include a boost (step-up) converter configured to boost the DC voltage from the external power source to a certain voltage level for the second Vpp 526. In these and other embodiments, the first Vpp 524 may be lower than the second Vpp 526. For example, in some embodiments, the first Vpp 524 may be about 9V and the second Vpp 526 may be about 14V. In other embodiments, the first Vpp 524 and the second Vpp 526 may include other voltages, in which the second Vpp 526 remains higher than the first Vpp 524.

In some embodiments, the implementation of the first Vpp 524 and the second Vpp 526 may improve power efficiency of the programming power voltage compared to existing implementations using a single programming power voltage. For example, existing implementations use a buck-boost converter to generate a Vpp around 12V. In some instances, the generated Vpp may correspond to the voltage level of the external power, in which the buck-boost converter helps stabilize the external power for the NAND memory 500. Such existing implementation delivers the Vpp to the NAND memory 500 with a power efficient level of around 85 %. The first Vpp 524 and the second Vpp 526 of the present disclosure may be provided to the NAND memory 500 with improved efficiency.

For example, in some embodiments, the first Vpp 524 and the second Vpp 526 may be obtained from power circuitry 564. In some examples, the power circuitry 564 is similar or analogous to the external power circuitry 464 of FIG. 4. The power circuitry 564 may be a part of a device or system utilizing the NAND memory 500. For example, the power circuitry 564 may be part of an SSD utilizing the NAND memory 500. In some embodiments, the power circuitry 564 may be or include the external power circuitry 464 of FIG. 4. For example, power circuitry may be configured to generate the first Vpp 524, the second Vpp 526, the first supply voltage 402, and the second supply voltage 404. In other embodiments, the power circuitry 554 may be separate from the external power circuitry 464.

In some embodiments, the power circuitry 564 may include a buck converter 568 configured to generate the first Vpp 524. For example, the buck converter 568 may be configured to convert power obtained from a power source 562 to generate the first Vpp 524. In some embodiments, the power circuitry 564 may include a boost converter 566 configured to generate the second Vpp 526. For example, the boost converter 566 may be configured to boost the power form the power source 562 to generate the second Vpp 526. In these and other embodiments, the first Vpp 524 and the second Vpp 526 generated using the power circuitry 564 may provide improved efficiencies compared to a single Vpp generated using conventional systems or power circuitry including a buck-boost converter. For example, the first Vpp 524 generated using the buck converter 568 may have an improved efficiency of around 96 %, and the second Vpp 526 generated using the boost converter 566 may have an improved efficiency of around 96 % compared to the 85 % efficiency of the single Vpp generated using conventional systems. The efficiencies are provided as examples and may include other values or ranges. Additionally, the first Vpp 524 and the second Vpp 526 provided to the NAND memory 500 separately may permit the NAND memory 500 to operate using multiple Vpps without additional voltage regulators or converters within the NAND memory 500.

With reference still to FIG. 5, in some embodiments, the pass voltage 516 (denoted by Vpass) may be generated based on the first Vpp 524 and the second Vpp 526. For example, in some embodiments, the NAND memory 500 may include a first multiplexer (MUX) 528 configured to select an input voltage between the first Vpp 524 and the second Vpp 526 based on a type of operation between performed by the NAND memory 500. For example, the first MUX 528 may be configured to communicate with the local controller 135 which may provide a selection signal based on the type of operation being performed. In some embodiments, the first MUX 528 may be configured to select between an operation related to the SSD or management. For example, the SSD operations may include data-related operations that the SSD performs with respect to the NAND memory 500 when interacting with a host system. For example, the SSD operations may include read operation, write operation, erase operation, etc. The NAND management operations may include operations or processes performed to maintain or improve the longevity, performance, and/or integrity of the SSD. For example, the NAND management operations may include wear leveling in which the NAND memory 500 distributes the data written on the memory cells 522 to reduce chances of any single cell from being written to excessively. Some other NAND management operations may include garbage collection, block management, error correction, bad block management, etc. In these and other embodiments, the first MUX 528 may select between the SSD operations and the NAND management operations based on commands from the local controller 135.

In some embodiments, the first MUX 528 may include a second MUX configured to select input voltage for the first MUX between the first Vpp 524 and the second Vpp 526 based on the type of SSD operation being performed. For example, the second MUX may be configured to select the first Vpp 524 for the read operation and the second Vpp 526 for the program operation. In these and other embodiments, the first MUX 528 may be configured to select between the Vpp selected by the second MUX and the second Vpp 526. For example, the first MUX 528 may select the VPP selected by the second MUX for the SSD operations and the second Vpp 526 for the NAND management operations.

In some embodiments, the first MUX 528 may be configured to receive additional voltage to be added to the second Vpp 526. For example, during a program operation, whether SSD or NAND management, the second Vpp 526 may not be sufficient (e.g., the voltage could be lower than required by the NAND). In such instances, the second Vpp 526 may be increased by the additional voltage generated using the second charge pump 512 to generate the pass voltage 516.

The pass voltage 516 is passed to global word lines (GWL 518). In some examples, the GWL 518 is similar to the GWL 418 of FIG. 4. The GWL 518 is a control signal line that connects to local word lines across different layers of blocks in the NAND memory 500. The GWL 518 may allow the local controller to select the row of the memory cells 522 to operate on and to facilitate transfer of the program voltage 514 and/or the pass voltage 516 to the selected rows of the memory cells 522. In some examples, the NAND memory 500 may include a select gate (SG) 520 configured to control the connection of the NAND string to the bit line and source line, facilitating data access. The SG 520 may control whether current can enter and exit the NAND string, such that the operations may be performed with respect to the memory cells 522.

In one example the local controller and control logic associated therewith (e.g., the local controller 135 of FIG. 1) may be configured to determine the type of operation to be performed by the NAND memory 500. For example, the local controller 135 may determine that the NAND memory 500 is to perform a first type of operation. In response to determining that the NAND memory 500 is to perform the first type of operation, the local controller 135 may cause the first Vpp 524 to be applied to the GWL 518 of the memory array. In another example, the local controller 135 may determine that the NAND memory 500 is to perform a second type of operation. In response to determining that the NAND memory 500 is to perform the second type of operation, the local controller 135 may cause the second Vpp 526 to be applied to the GWL 518 of the memory array. In some examples, the first type of operation may be the read operation, and the second type operation may be the program operation.

Modifications, additions, or omissions may be made to FIG. 5 without departing from the scope of the present disclosure. For example, the NAND memory 500 may include more or fewer elements than those illustrated and described in the present disclosure. In some embodiments, the NAND memory 500 may correspond to, include, or be a part of the NAND memory 400 of FIG. 4. For example, the parts of the NAND memory 500 may be combined with the NAND memory 400.

With reference to FIG. 6, FIG. 6 illustrates an example charge pump 609, in accordance with one or more embodiments of the present disclosure. In some embodiments, the charge pump 609 may correspond to the first charge pump 410 and/or the second charge pump 412 of FIG. 4. In some embodiments, the charge pump 409 may be configured to obtain an input voltage 640 (denoted by Vin). The input voltage 640 may correspond to programming power voltage (Vpp).

In some embodiments, the charge pump 609 may include a set of amplification stages 644. For example, the set of amplification stages 644 may include a first amplification stage 644a, a second amplification state 644b, and a third amplification stage 644c (collectively referred to as the amplification stages 644). The amplification stages 644 may include stages of voltage conversion configured to amplify the input voltage 640 in a stepwise manner. For example, each amplification stage of the set of amplification stages 644 may be configured to provide a certain level of amplification with respect to the input voltage 640. While FIG. 6 illustrates three amplification stages (644a-644c), the charge pump 609 may include any other suitable or necessary number of stages.

In some embodiments, each stage of the set of amplification stages 644 may include a voltage converter configured to boost the input voltage 640. For example, the second amplification stage 644b may include a voltage converter 632. In some embodiments, the voltage converter 632 may include a clock driver 634, a booster 636, and a pass-gate 638. In some embodiments, the pass-gate 638 may be configured to generate an output voltage (denoted by Vout in FIG. 6) based on the input voltage 640 and a booster voltage (denoted by Vboost in FIG. 6). For example, the pass-gate 638 may add the booster voltage to the input voltage 640 to generate the output voltage. In some embodiments, the pass-gate 638 may be or include MOSFETs or transistors configured to operate as a switch. The pass-gate 638 may be configured to allow charge from one point to another depending on the control signals. For example, the pass-gate 638 may allow the charge (e.g., the booster voltage) from the booster 636 to be added to the input voltage 640.

In some embodiments, the voltage converter 632 may be configured to operate using multiple supply voltages. For example, the booster 636 may be configured to operate using a second supply voltage 604 and the clock driver 634 may be configured to operate using a first supply voltage 602. In some embodiments, the first supply voltage 602 and the second supply voltage 604 may correspond to the first supply voltage 402 and the second supply voltage 404 of FIG. 4, respectively. In these and other embodiments, the booster 636 may be configured to generate the booster voltage using the second supply voltage 604. For example, the booster 636 may apply the second supply voltage 604 to a capacitor, such that the capacitor begins to store charge. In some embodiments, the capacitor may be configured to hold the charge corresponding to the second supply voltage 604. The stored charge may be transferred to the pass-gate 638 such that the pass-gate may add the booster voltage to the input voltage 640. In some embodiments, the use of the second supply voltage 604, which is higher than the first supply voltage 602 may permit the booster 636 to generate a higher booster voltage (corresponding to the second supply voltage 604) without a need for additional boosting circuitry.

For example, existing charge pumps may implement boosters using Vcc or only the first supply voltage 602. In such implementations, efficiency of the charge pump is reduced with each stage of the amplification. Additionally, such implementation requires increased area or form factor. Contrastingly, the charge pumps in accordance with some embodiments of the present application provide the higher supply voltage (e.g., the second supply voltage 604) directly to the booster 636 without additional booster circuitry. The direct supply of the second supply voltage 604 may help reduce the area or form factor and improve the efficiency of the booster 636. As the charge pump 609 includes multiple amplification stages 644, the efficiency of the charge pump 609 may increase with each stage of the amplification.

In some embodiments, the clock driver 634 may be configured to provide clock signals for the voltage converter 632. For example, the clock driver 634 may generate clock signals that control the booster 636 and/or the pass-gate 638. For example, the clock driver 634 may help synchronize the operation of the voltage converter 632. The clock signal generated by the clock driver 634 may control the timings of turning on and off the charge capacitors. In some embodiments, the clock driver 634 may be powered using the first supply voltage 402. For example, the clock driver 634 may use the first supply voltage 602 to energize components such as oscillators, buffers, and/or inverters that generate the clock signal. The clock driver 634 does not require the use of increased voltage such as the second supply voltage 604 and may be powered using the first supply voltage 602.

In some embodiments, the charge pump 609 may correspond to the first charge pump 510 of FIG. 5 (e.g., Vpgm_cp) configured to generate the program voltage 514. In such instances, the initial input voltage may correspond to a programming power voltage (Vpp). In instances in which the NAND memory 500 of FIG. 5 is operating using multiple programming power voltages, the input voltage may be selected as the higher of the multiple programming power voltages. For example, in some embodiments, a NAND memory may receive a first Vpp 624 and a second Vpp 626. In these and other embodiments, a Vpp detector 648 may be configured to detect the first Vpp 624 and the second 6pp 526. The Vpp detector 648 may provide a select signal for a multiplexer 646 configured to select between the first Vpp 624 and the second Vpp 626.

Modifications, additions, or omissions may be made to FIG. 6 without departing from the scope of the present disclosure. For example, the charge pump 609 may include more or fewer elements than those illustrated and described in the present disclosure.

FIG. 7 illustrates a flowchart showing a method or methods that support techniques for implementing techniques for pass voltage determination with power supply differentiation in accordance with examples as disclosed herein. Method 700 may be performed by, for example, a memory controller (e.g., local controller 135), which may be implemented using the NAND memory 400, the NAND memory 500, and/or the charge pump 609.

In one example, method 700 includes a block 702, which includes identifying a type of operation to be performed by the NAND memory (e.g., NAND memory 400 of FIG. 4 and/or the NAND memory 500 of FIG. 5). For example, the memory controller (e.g., local controller 135) may determine a type of operation being performed by the NAND memory. The operations may include SSD operations, such as read, program, erase, etc. and NAND management operations. In some embodiments, the memory controller may determine the type of operation being performed based on a communication with a system controller (e.g., system controller 115) of the SSD.

Block 704 of method 700 includes selecting between using a first programming power voltage and a second programming power voltage with respect to a pass voltage based on the type of operation to be performed by the NAND memory. In some embodiments, the pass voltage may be applied to one or more memory cells of a set of memory cells of the NAND memory.

It should be noted that the described techniques include possible implementations, and that the operations and the blocks may be rearranged, reordered, or otherwise modified and that other implementations are possible. Further, portions from two or more of the methods may be combined.

Information and signals described herein may be represented using any of a variety of different technologies and techniques. For example, data, instructions, commands, information, signals, bits, or symbols of signaling that may be referenced throughout the above description may be represented by voltages, currents, electromagnetic waves, magnetic fields or particles, optical fields or particles, or any combination thereof. Some drawings may illustrate signals as a single signal; however, the signal may represent a bus of signals, where the bus may have a variety of bit widths.

The terms “electronic communication,” “conductive contact,” “connected,” and “coupled” may refer to a relationship between components that supports the flow of signals between the components. Components are considered in electronic communication with (or in conductive contact with or connected with or coupled with) one another if there is any conductive path between the components that can, at any time, support the flow of signals between the components. At any given time, the conductive path between components that are in electronic communication with each other (or in conductive contact with or connected with or coupled with) may be an open circuit or a closed circuit based on the operation of the device that includes the connected components. The conductive path between connected components may be a direct conductive path between the components or the conductive path between connected components may be an indirect conductive path that may include intermediate components, such as switches, transistors, or other components. In some examples, the flow of signals between the connected components may be interrupted for a time, for example, using one or more intermediate components such as switches or transistors.

The term “coupling” (e.g., “electrically coupling”) may refer to a condition of moving from an open-circuit relationship between components in which signals are not presently capable of being communicated between the components over a conductive path to a closed-circuit relationship between components in which signals are capable of being communicated between components over the conductive path. If a component, such as a controller, couples other components together, the component initiates a change that allows signals to flow between the other components over a conductive path that previously did not permit signals to flow.

The term “isolated” refers to a relationship between components in which signals are not presently capable of flowing between the components. Components are isolated from each other if there is an open circuit between them. For example, two components separated by a switch that is positioned between the components are isolated from each other if the switch is open. If a controller isolates two components, the controller affects a change that prevents signals from flowing between the components using a conductive path that previously permitted signals to flow.

The terms “if,” “when,” “based on,” or “based at least in part on” may be used interchangeably. In some examples, if the terms “if,” “when,” “based on,” or “based at least in part on” are used to describe a conditional action, a conditional process, or connection between portions of a process, the terms may be interchangeable.

The term “in response to” may refer to one condition or action occurring at least partially, if not fully, as a result of a previous condition or action. For example, a first condition or action may be performed and second condition or action may at least partially occur as a result of the previous condition or action occurring (whether directly after or after one or more other intermediate conditions or actions occurring after the first condition or action).

The devices discussed herein, including a memory array, may be formed on a semiconductor substrate, such as silicon, germanium, silicon-germanium alloy, gallium arsenide, gallium nitride, etc. In some examples, the substrate is a semiconductor wafer. In some other examples, the substrate may be a silicon-on-insulator (SOI) substrate, such as silicon-on-glass (SOG) or silicon-on-sapphire (SOP), or epitaxial layers of semiconductor materials on another substrate. The conductivity of the substrate, or sub-regions of the substrate, may be controlled through doping using various chemical species including, but not limited to, phosphorous, boron, or arsenic. Doping may be performed during the initial formation or growth of the substrate, by ion-implantation, or by any other doping means.

A switching component or a transistor discussed herein may represent a field-effect transistor (FET) and comprise a three terminal device including a source, drain, and gate. The terminals may be connected to other electronic elements through conductive materials, e.g., metals. The source and drain may be conductive and may comprise a heavily-doped, e.g., degenerate, semiconductor region. The source and drain may be separated by a lightly-doped semiconductor region or channel. If the channel is n-type (i.e., majority carriers are electrons), then the FET may be referred to as an n-type FET. If the channel is p-type (i.e., majority carriers are holes), then the FET may be referred to as a p-type FET. The channel may be capped by an insulating gate oxide. The channel conductivity may be controlled by applying a voltage to the gate. For example, applying a positive voltage or negative voltage to an n-type FET or a p-type FET, respectively, may result in the channel becoming conductive. A transistor may be “on” or “activated” if a voltage greater than or equal to the transistor’s threshold voltage is applied to the transistor gate. The transistor may be “off” or “deactivated” if a voltage less than the transistor’s threshold voltage is applied to the transistor gate.

The description set forth herein, in connection with the appended drawings, describes example configurations and does not represent all the examples that may be implemented or that are within the scope of the claims. The term “exemplary” used herein means “serving as an example, instance, or illustration” and not “preferred” or “advantageous over other examples.” The detailed description includes specific details to provide an understanding of the described techniques. These techniques, however, may be practiced without these specific details. In some instances, well-known structures and devices are shown in block diagram form to avoid obscuring the concepts of the described examples.

In the appended figures, similar components or features may have the same reference label. Further, various components of the same type may be distinguished by following the reference label by a hyphen and a second label that distinguishes among the similar components. If just the first reference label is used in the specification, the description is applicable to any one of the similar components having the same first reference label irrespective of the second reference label.

The functions described herein may be implemented in hardware, software executed by a processor, firmware, or any combination thereof. If implemented in software executed by a processor (e.g., processor 310 of FIG. 3), the functions may be stored on or transmitted over, as one or more instructions or code, a computer-readable medium. Other examples and implementations are within the scope of the disclosure and appended claims. For example, due to the nature of software, the described functions can be implemented using software executed by a processor, hardware, firmware, hardwiring, or combinations of any of these. Features implementing functions may also be physically located at various positions, including being distributed such that portions of functions are implemented at different physical locations.

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

The description herein is provided to enable a person skilled in the art to make or use the disclosure. Various modifications to the disclosure will be apparent to those skilled in the art, and the generic principles defined herein may be applied to other variations without departing from the scope of the disclosure. Thus, the disclosure is not limited to the examples and designs described herein but is to be accorded the broadest scope consistent with the principles and novel features disclosed herein.

What is claimed is:

1. A NAND flash memory, comprising:
an array of memory cells comprising a plurality of memory cells;
a first programming power voltage pad configured to receive a first programming power voltage (Vpp1);
a second programming power voltage pad configured to receive a second programming power voltage (Vpp2), the second programming power voltage being higher voltage than the first programming power voltage; and
a control logic configured to:
select between using the first programming power voltage and the second programming power voltage with respect to a pass voltage (Vpass) based on a type of operation of the NAND flash memory, the pass voltage being applied to one or more memory cells of the plurality of memory cells.

2. The NAND flash memory of claim 1, further comprising:
a first supply voltage pad configured to receive a first supply voltage (Vcc1); and
a second supply voltage pad configured to receive a second supply voltage (Vcc2), the second supply voltage being higher than the first supply voltage.

3. The NAND flash memory of claim 2, further comprising:
a Vpass charge pump configured to provide additional voltage for the Vpass voltage using the first supply voltage, the Vpass charge pump comprising:
a booster configured to generate a boost voltage based on the second supply voltage;
a clock driver configured to provide timing signals for the booster using the first supply voltage; and
a pass-gate configured to generate the Vpass voltage based on an input voltage and the boost voltage.

4. The NAND flash memory of claim 3, wherein the second programming power voltage is provided as the input voltage to the Vpass charge pump to be pumped up to a voltage level required for one or more of: a write SSD operation, an erase SSD operation, or a management operation.

5. The NAND flash memory of claim 2, further comprising:
a program charge pump configured to provide a program voltage to the array of memory cells based on the type of operation of the NAND flash memory, the program charge pump comprising:
a booster configured to generate a boost voltage based on the second supply voltage;
a clock driver configured to provide timing signals for the booster using the first supply voltage; and
a pass-gate configured to generate the program voltage based on an input voltage and the boost voltage.

6. The NAND flash memory of claim 5, wherein the input voltage of the program charge pump is selected between using the first programming power voltage and using the second programming power voltage.

7. The NAND flash memory of claim 2, further comprising:
a pump configured to stabilize the first supply voltage to a particular voltage.

8. The NAND flash memory of claim 2, further comprising:
a pump configured to stabilize the second supply voltage to a particular voltage.

9. The NAND flash memory of claim 7, wherein the particular voltage is between 1.2 and 2.35 V.

10. The NAND flash memory of claim 1, wherein the program charge pump includes a plurality of boost stages, each boost stage of the plurality of boost stages comprising a respective booster, clock driver, and pass-gate.

11. The NAND flash memory of claim 1, wherein the type of operation is selected from: a synchronous read solid-state drive (SSD) operation, an asynchronous read SSD operation, a write SSD operation, an erase SSD operation, or a management operation, each operation addressing one or more planes of the NAND flash memory.

12. The NAND flash memory of claim 11, wherein the control logic selects using the first programming power voltage with respect to the pass voltage for the read SSD operation.

13. The NAND flash memory of claim 11, wherein the control logic selects using the second programming power voltage with respect to the pass voltage for the write SSD operation and the management operation.

14. The NAND flash memory of claim 1, wherein the first programming power voltage is obtained from external power management circuitry comprising a step-down voltage regulator configured to:
obtain an external input voltage from a power source; and
generate the first programming power voltage having lower voltage than the external input voltage from the power source.

15. The NAND flash memory of claim 1, wherein the second programming power voltage is obtained from external power circuitry comprising a step-up voltage regulator configured to:
obtain an external input voltage from a power source; and
generate the second programming power voltage having higher voltage than the external input voltage from the external input voltage.

16. The NAND flash memory of claim 1, wherein the control logic includes a multiplexer configured to select between first programming voltage and the second programming power voltage.

17. A NAND flash memory, comprising:
an array of memory cells comprising a plurality of memory cells;
a first supply voltage pad configured to receive a first supply voltage (Vcc1);
a second supply voltage pad configured to receive a second supply voltage (Vcc2), the second supply voltage being higher than the first supply voltage; and
a charge pump comprising:
a booster configured to generate a boost voltage based on the second supply voltage; and
a clock driver configured to provide timing signals for the booster using the first supply voltage.

18. The NAND flash memory of claim 17, further comprising:
a control logic configured to:
select between using a first programming voltage and a second programming voltage with respect to a pass voltage (Vpass) based on a type of operation of the NAND flash memory, the pass voltage being applied to one or more memory cells of the plurality of memory cells.

19. The NAND flash memory of claim 17, wherein the charge pump is a program charge pump configured to provide a program voltage to the array of memory cells based on a type of operation of the NAND flash memory.

20. The NAND flash memory of claim 17, wherein the charge pump is a pass charge pump configured to provide additional voltage for a pass voltage using the first supply voltage.

21. A method comprising:
identifying a type of operation to be performed by a NAND flash memory; and
selecting between using a first programming voltage and a second programming voltage with respect to a pass voltage (Vpass) based on the type of operation to be performed by the NAND flash memory, the pass voltage being applied to one or more memory cells of a plurality of memory cells of the NAND flash memory.
